(19) United States
(12) Patent Application Publication
(10) Pub. No.: US 2025/0331253 A1
(43) Pub. Date: Oct. 23, 2025

(54) HYBRID NANOWIRE AND NANOSHEET DEVICES

(71) Applicant: Taiwan Semiconductor Manufacturing Co., Ltd., Hsinchu (TW)

(72) Inventors: Chih-Chao Chou, Hsinchu (TW); Yi-Bo Liao, Hsinchu (TW); Yi-Hsun Chiu, Zhubei City (TW); Ching-Wei Tsai, Hsinchu (TW); Chih-Hao Wang, Baoshan Township (TW)

(21) Appl. No.: 19/259,866

(22) Filed: Jul. 3, 2025

Related U.S. Application Data
(63) Continuation of application No. 18/797,298, filed on Aug. 7, 2024.
(60) Provisional application No. 63/565,154, filed on Mar. 14, 2024.

(51) Int. Cl. H10D 62/10; H10B 10/00; H10D 30/01; H10D 30/43; H10D 30/67; H10D 84/01; H10D 84/03; H10D 84/83

(52) U.S. Cl. CPC H10D 62/121; H10B 10/125; H10D 30/014; H10D 30/43; H10D 30/6735; H10D 30/6757; H10D 84/0128; H10D 84/038; H10D 84/83

(57) ABSTRACT

A method includes patterning stacked layers to form a first multi-layer stack and a second multi-layer stack, each including a plurality of sacrificial layers and a plurality of nanostructures located alternatingly. The second multi-layer stack is wider than the first multi-layer stack. A nanosheet transistor is formed based on the first multi-layer stack. The nanosheet transistor includes first channel regions having a first width, and a first gate stack on the first channel regions. A nanowire transistor is formed based on the second multi-layer stack. The nanowire transistor includes second channel regions narrower than the first channel regions, and a second gate stack on the second channel regions.

### PRIORITY CLAIM AND CROSS-REFERENCE

This application is a continuation of U.S. patent application Ser. No. 18/797,298, filed on Aug. 7, 2024, which application claims the benefit of the following provisionally filed U.S. Patent application: Application No. 63/565,154, filed on Mar. 14, 2024, and entitled “SEMICONDUCTOR STRUCTURE AND METHOD FOR MANUFACTURING THE SAME,” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 through FIGS. 14A-1, 14A-2, 14B-1, and 14B-2 illustrate the views of intermediate stages in the formation of a nanosheet transistor and a nanowire transistor in accordance with some embodiments.

FIGS. 15A-1, 15A-2, 15B-1, and 15B-2 through FIGS. 17A-1, 17A-2, 17B-1, and 17B-2 illustrate the views of intermediate stages in the formation of a nanosheet transistor and a nanowire transistor in accordance with alternative embodiments.

FIGS. 18-21 illustrate the top views of some nanowires and nanosheets in accordance with some embodiments.

FIG. 22 illustrates the circuit schematic of a static random-access memory (SRAM) cell in accordance with some embodiments.

FIG. 23 illustrates some nanosheet transistors having different channel widths in accordance with some embodiments.

FIG. 24 illustrates some nanowire transistors having different channel widths in accordance with some embodiments.

FIG. 25 illustrates a process flow for forming a nanosheet transistor and a nanowire transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A hybrid structure including a nanosheet (NS) transistor and a nanowire (NW) transistor and the method of forming the same are provided. In accordance with some embodiments of the present disclosure, the nanosheet transistor and the nanowire transistor share some common formation processes. The thickness of the nanowires in the nanowire transistor are increased by epitaxially growing a semiconductor material. By forming the hybrid structure in circuits, the occupied chip area is reduced without sacrificing circuit performance.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

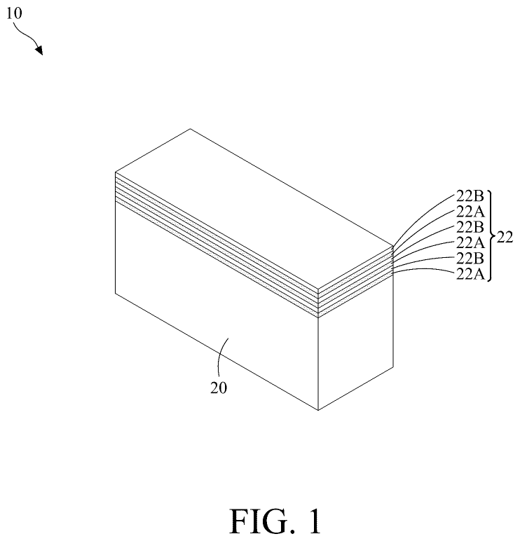

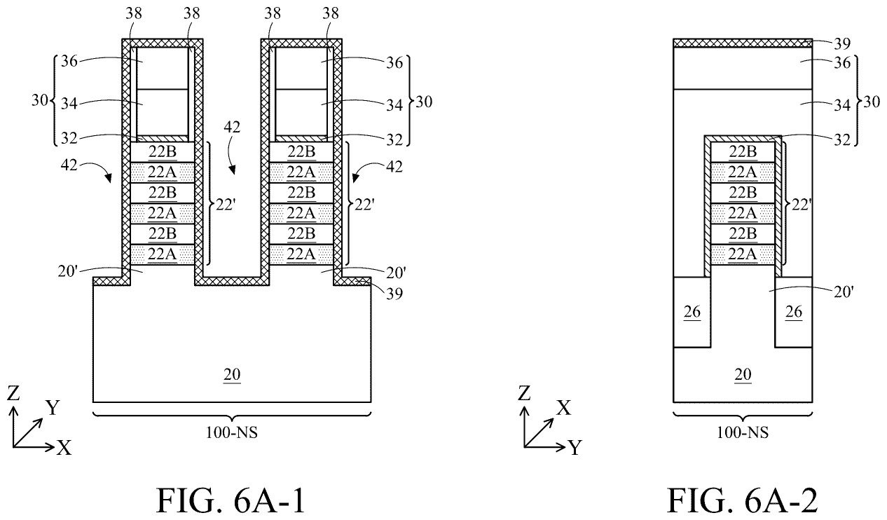

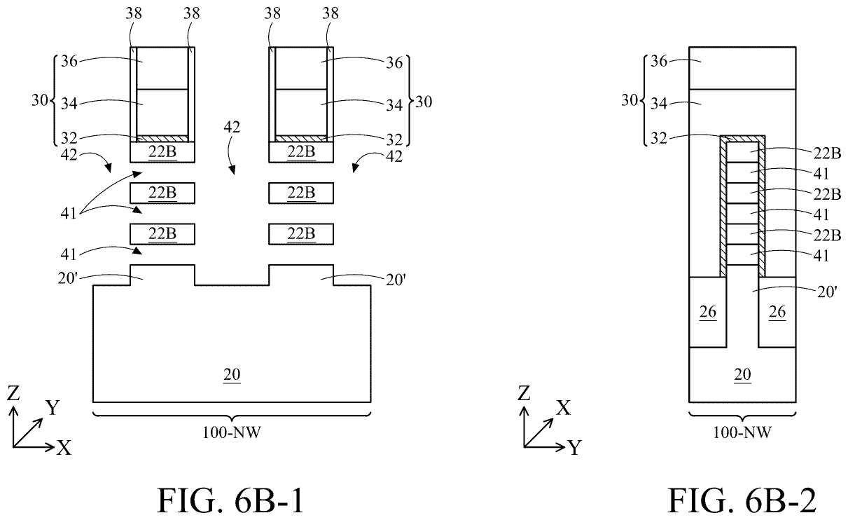

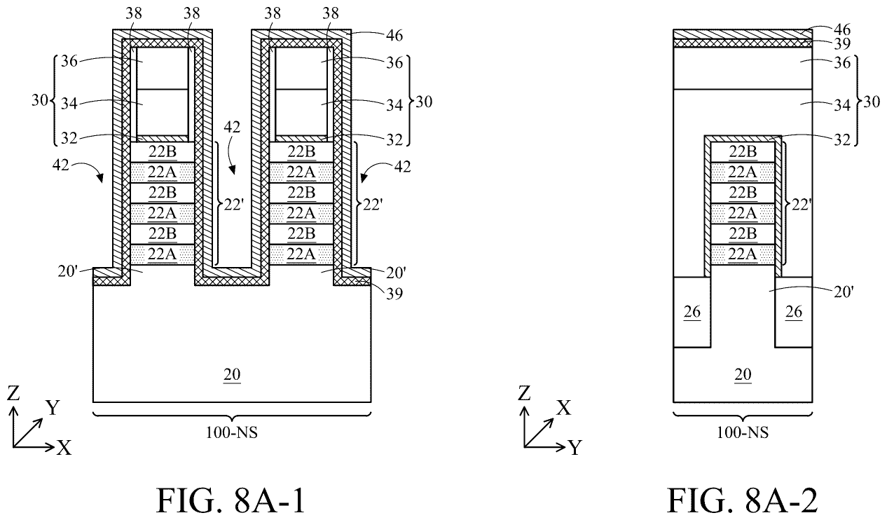

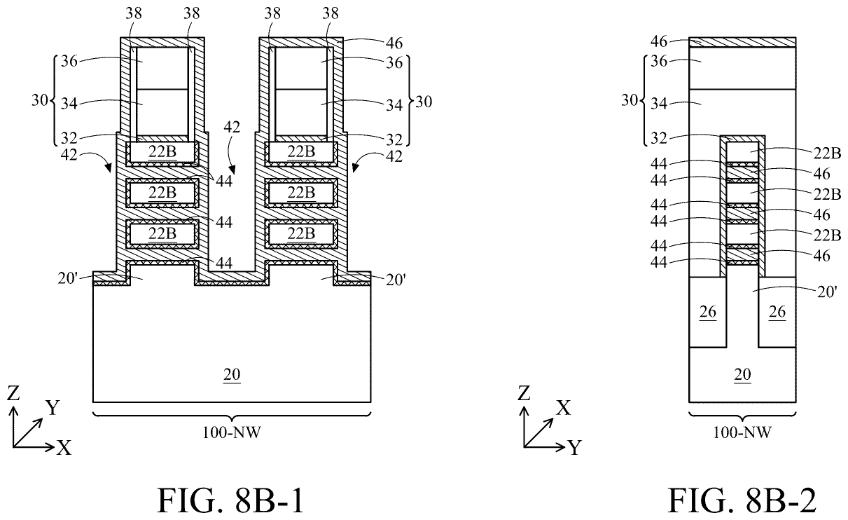

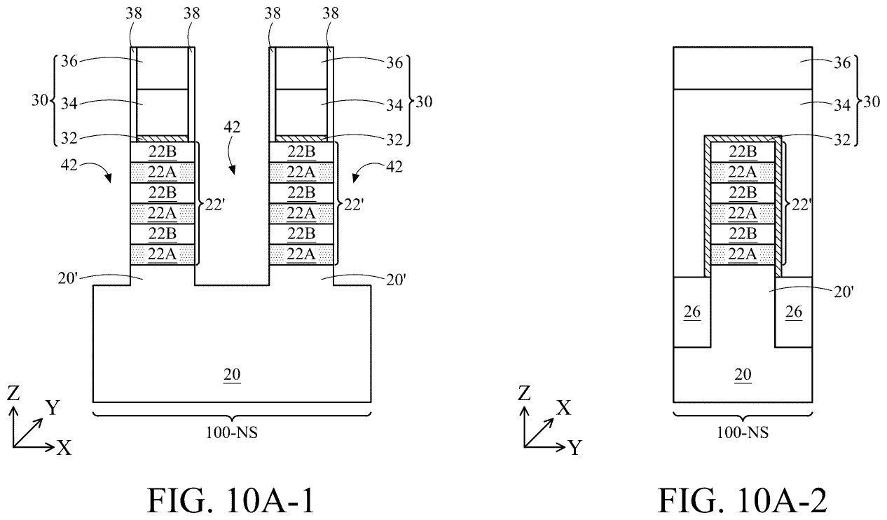

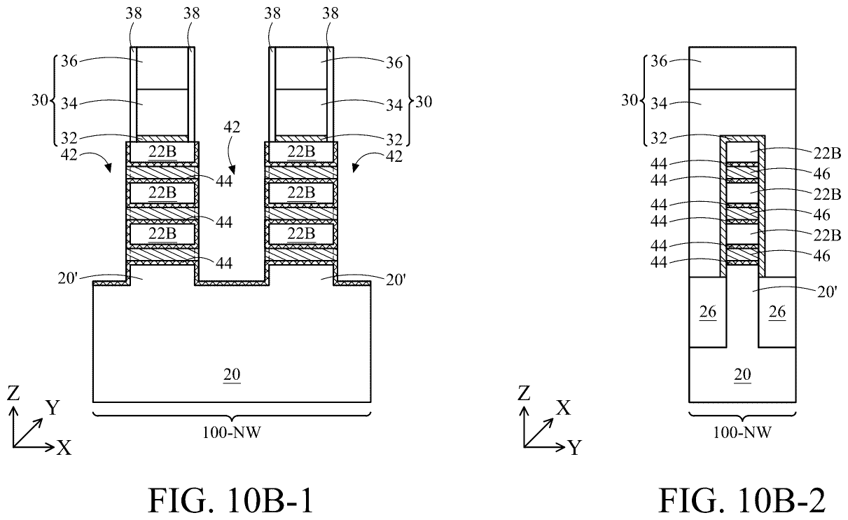

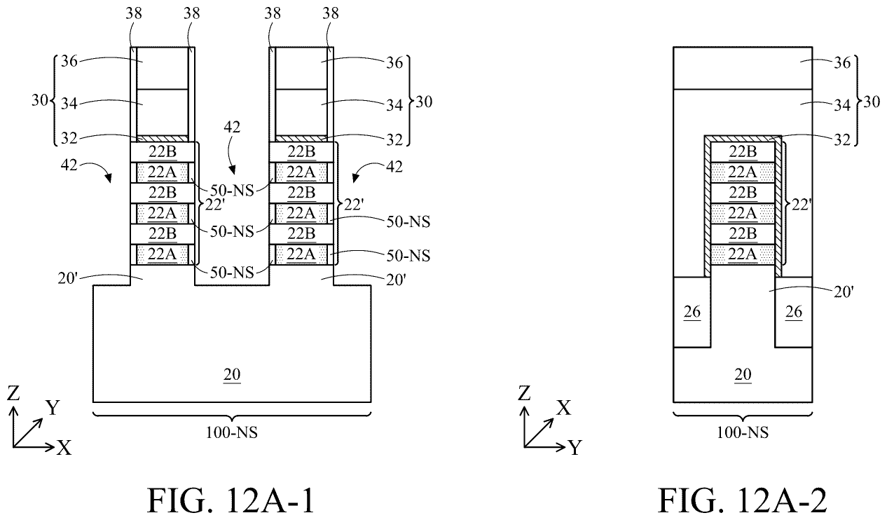

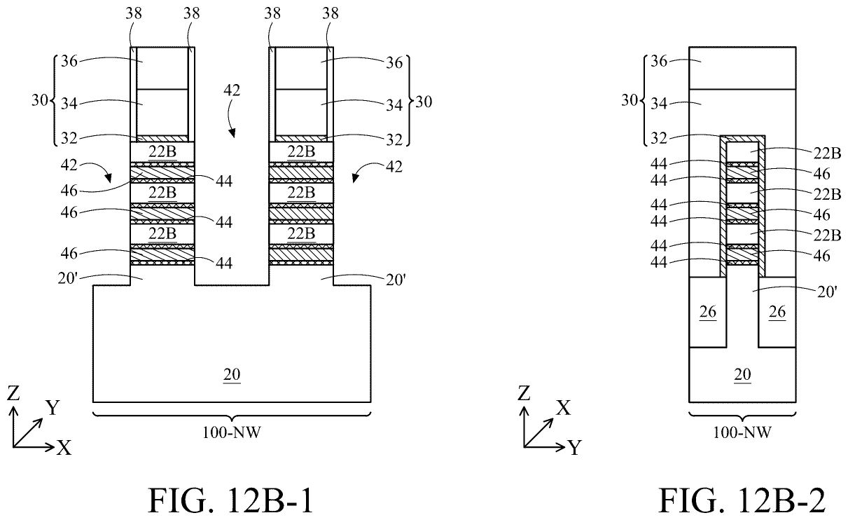

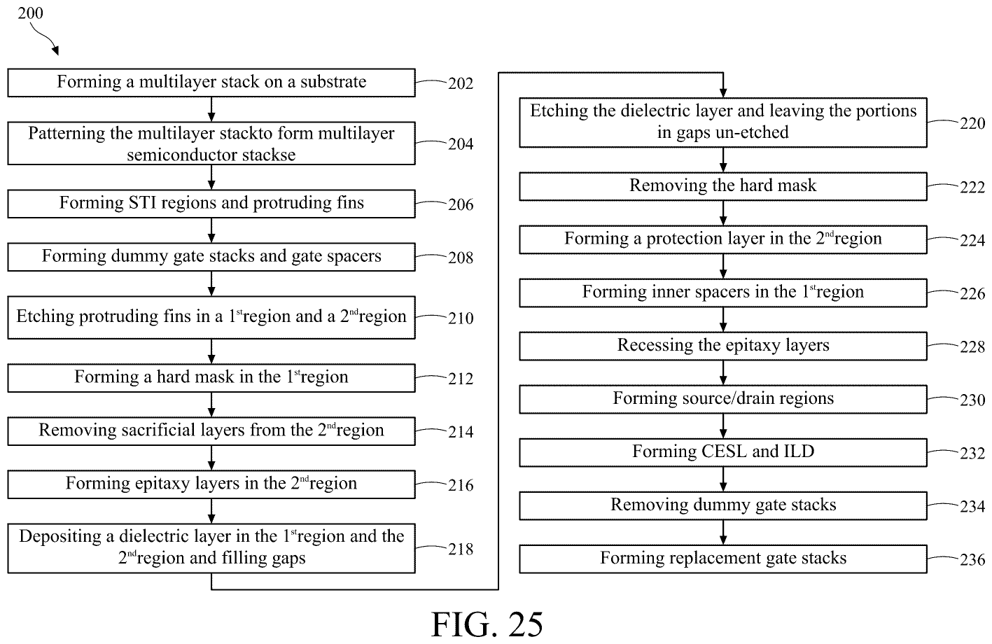

FIGS. 1 through FIGS. 14A-1, 14A-2, 14B-1, and 14B-2 illustrate the cross-sectional views of intermediate stages in the formation of a hybrid structure including a nanosheet transistor and a nanowire transistor in accordance with some embodiments of the present disclosure. The corresponding processes are also reflected schematically in the process flow shown in FIG. 25.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 25. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

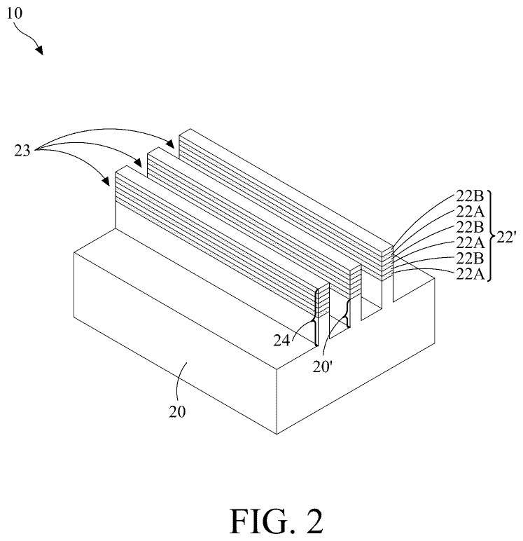

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 25. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

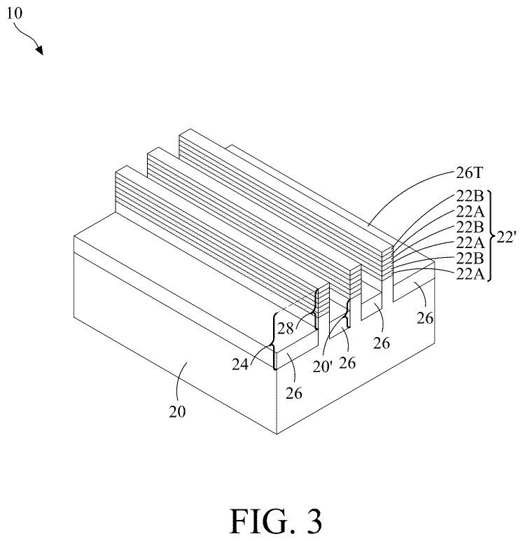

FIG. 3 illustrates the formation of isolation regions 26, which are also referred to as Shallow Trench Isolation (STI) regions throughout the description. The respective process is illustrated as process 206 in the process flow 200 shown in FIG. 25. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

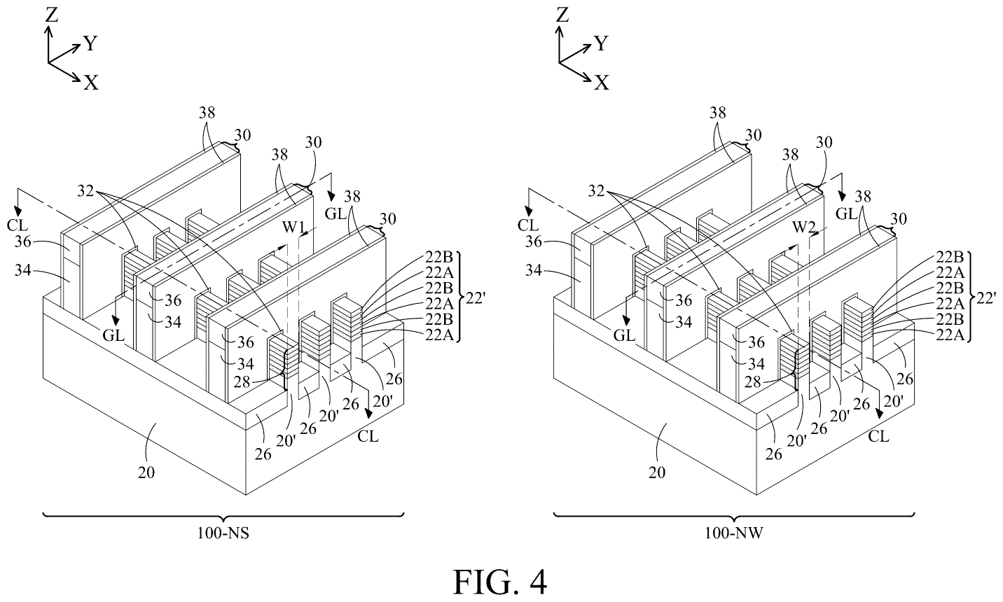

Next, FIG. 4 illustrates two device regions 100-NS and 100-NW, which are for forming a nanosheet transistor and a nanowire transistor, respectively, with both also being referred to as Gate-All-Around transistors. The structures formed in device regions 100-NS and 100-NW may share same formation process including the processes as shown in FIGS. 1 through 3. The width W1 of the multilayer stacks 22′ in device region 100-NS is greater than the width W2 of the multilayer stacks 22′ in device region 100-NW. Accordingly, the thicknesses and the materials in device region 100-NS may be the same as the thicknesses and the materials of the corresponding features in device region 100-NW.

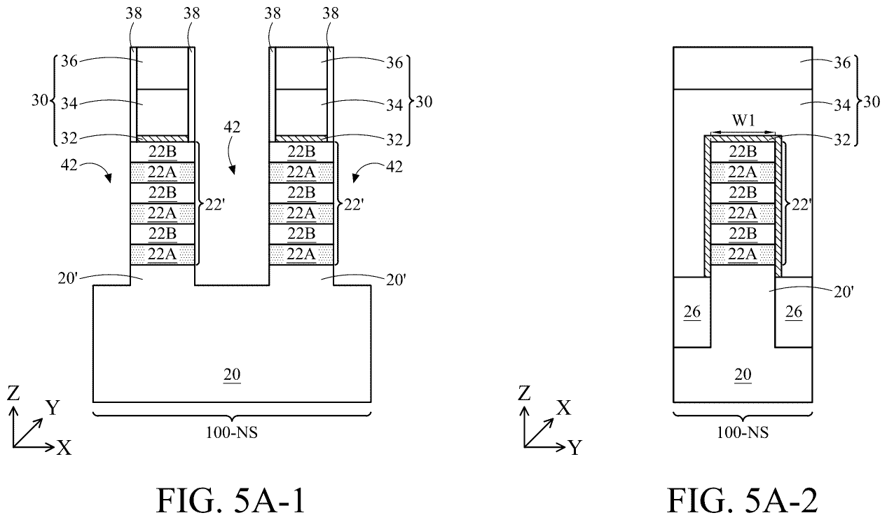

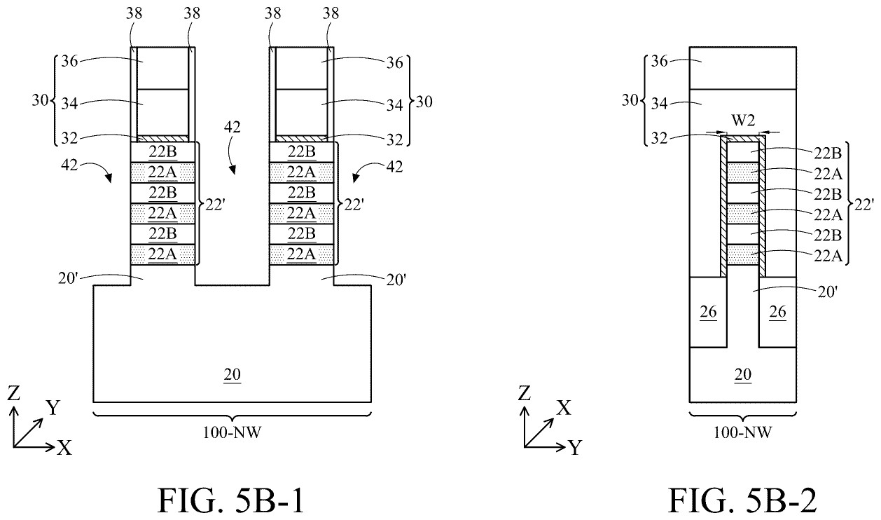

In accordance with some embodiments, width W1 (also refer to FIG. 5A-2) may be in the range between about 8 nm and about 30 nm, and may be in the range between about 8 and about 13 nm. Width W2 (also refer to FIG. 5B-2) may be in the range between about 4 nm and about 6 nm. Ratio W1/W2 may be in the range between about 1.5 and about 7.5 in accordance with some embodiments.

Further referring to FIG. 4, dummy gate stacks 30 and gate spacers 38 are formed on the top surfaces and the sidewalls of (protruding) fins 28. The respective process is illustrated as process 208 in the process flow 200 shown in FIG. 25. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

FIGS. 5A-1 and 5A-2 illustrate the cross-sectional views of the structure shown in the device region 100-NS in FIG. 4, in which a nanosheet transistor is to be formed. FIG. 5A-1 illustrates the reference cross-section CL-CL (with “CL” representing Channel-Length) in FIG. 4, which cross-section cuts through a protruding fin 28. FIG. 5A-2 illustrates the reference cross-section GL-GL (with “GL” representing Gate-Longitudinal) in FIG. 4, which reference cross-section is parallel to the gate lengthwise direction. Throughout the description, the figures with the figure numbers including “A-1” or “A-2” are obtained from the device region 100-NS, and are obtained from the cross-sections CL-CL and GL-GL, respectively. The figures with the figure numbers including “B-1” or “B-2” are obtained from the device region 100-NW, and are obtained from the cross-sections CL-CL and GL-GL, respectively.

Referring to FIGS. 5A-1, 5A-2, 5B-1, and 5B-2, the portions of protruding fins 28 (FIG. 4) that are not directly underlying dummy gate stacks 30 and gate spacers 38 are recessed through an etching process to form recesses 42. The respective process is illustrated as process 210 in the process flow 200 shown in FIG. 25. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than the bottoms of multilayer semiconductor stacks 22′. The etching may be anisotropic, so that the sidewalls of multilayer semiconductor stacks 22′ facing recesses 42 are vertical and straight.

In FIG. 4, X-axis, Y-axis, and Z-axis are marked. The X-axis, Y-axis, and Z-axis are also marked in subsequent figures for a clear view of the directions of the features.

FIGS. 6A-1 and 6A-2 illustrate the formation of hard mask 39 in device region 100-NS. The respective process is illustrated as process 212 in the process flow 200 shown in FIG. 25. In accordance with some embodiments, hard mask 39 is deposited as a blanket layer, and may be formed using a conformal deposition process such as ALD, CVD, or the like. A patterning process is then performed to remove the portion of hard mask 39 in device region 100-NW, leaving the hard mask 39 in device region 100-NS. Hard mask 39 may be formed of Al₂O₃, TiO₂, TiN, or the like, or may be formed of low-k dielectric materials such as SiOCN.

Next, the sacrificial semiconductor layers 22A in device region 100-NW are removed through an isotropic etching process, leaving the structure as shown in FIGS. 6B-1 and 6B-2. The respective process is illustrated as process 214 in the process flow 200 shown in FIG. 25. The etching is performed through recesses 42. The spaces left by the removed sacrificial semiconductor layers 22A are the gaps 41 between nanostructures 22B.

The etching of sacrificial semiconductor layers 22A may be achieved through a dry etching process or a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

Referring to FIGS. 7B-1 and 7B-2, epitaxy semiconductor layers 44 are grown on the exposed semiconductor materials through a selective epitaxy process. The respective process is illustrated as process 216 in the process flow 200 shown in FIG. 25. Accordingly, semiconductor layers 44 are formed on nanostructures 22B. The material of semiconductor layers 44 may be the same as or different from the material of nanostructures 22B. Accordingly, semiconductor layers 44 may be or may not be distinguishable from nanostructures 22B. The thickness of semiconductor layers 44 is well controlled, and semiconductor layers 44 cannot be too thick or too thin. If semiconductor layers 44 are too thick, the neighboring channels risk contacting with each other. If semiconductor layers 44 are too thin, the subsequently formed replacement gate stack may extend between neighboring semiconductor layers 44, causing the increase in parasitic capacitance. The thickness of semiconductor layers 44 may be in the range between about 1.5 nm and about 3.5 nm.

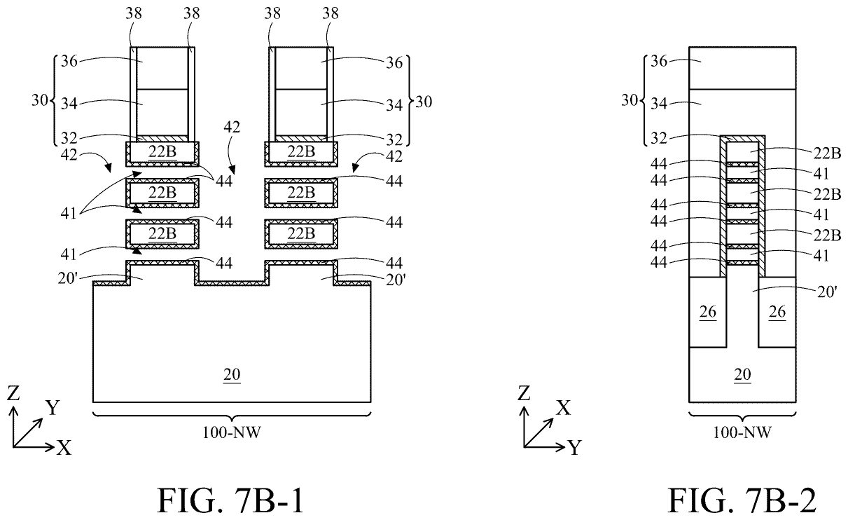

In accordance with some embodiments, semiconductor layers 44 are silicon layers, which are free from or substantially free from germanium therein, for example, with a germanium having an atomic percentage lower than about 1 percent. Semiconductor layers 44 may also comprise germanium, for example, with a germanium atomic percentage in the range between, and including, 0 percent and 100 percent. In the structure shown in FIG. 7B-2, semiconductor layers 44 are formed on the upper and lower surfaces of semiconductor nanostructures facing recesses 41.

The epitaxy is selective and semiconductor layers 44 are not formed on the exposed dielectric materials including gate spacers 38 and hard masks 36. This is achieved by adding an etching gas, such as HCl into the precursor gases for the epitaxy. The selective deposition may also be performed by performing etch-back processes after the deposition. The deposition and the etch-back processes may also be performed including a plurality of repeated deposition and etch-back cycles. The etch-back process may also be performed using an etching gas such as HCl. Accordingly, semiconductor layers 44 are not grown on hard mask 39, and device region 100-NS at the time during and after the epitaxy may also have the structure same as that is shown in FIGS. 6A-1 and 6A-2.

FIGS. 8A-1, 8A-2, 8B-1, and 8B-2 illustrate the deposition of dielectric layer 46 in accordance with some embodiments. The respective process is illustrated as process 218 in the process flow 200 shown in FIG. 25. Dielectric layer 46 may comprise silicon oxide, silicon oxycarbide, silicon oxy-carbo-nitride, or the like. The formation process may include a conformal deposition process such as ALD, CVD, or the like.

In device region 100-NS, as shown in FIGS. 8A-1 and 8A-2, dielectric layer 46 is formed conformally on hard mask 36. As shown in FIGS. 8B-1 and 8B-2, dielectric layer 46 includes the portions filling the recesses/gaps 41 (FIG. 7B-1), and also include some other portions on the exposed dielectric materials.

In a subsequent process, an isotropic etching process is performed to etch dielectric layer 46. The respective process is illustrated as process 220 in the process flow 200 shown in FIG. 25. Accordingly, the portions of dielectric layer 46 in device region 100-NS are removed, as shown in FIGS. 9A-1 and 9A-2, and hard mask layer 39 is exposed.

In device region 100-NW, as shown in FIGS. 9B-1 and 9B-2, the portions of dielectric layer 46 in the gaps between semiconductor layers 44 (and nanostructures 22B) have at least majority or all remaining as discrete dielectric layers (also referred to as dielectric layers 46), while the portions of dielectric layer 46 outside of the gaps are removed. The etching process may be performed through dry etching or wet etching, and the etching chemical is selected to etch dielectric layer 46, but does not etch gate spacers 38 and hard masks 36. For example, when dielectric layer 46 comprises silicon oxide, the dry etching may be performed using the mixture of NF₃ and NH₃ or the mixture of HF and NH₃. When wet etching is used, a HF solution may be used.

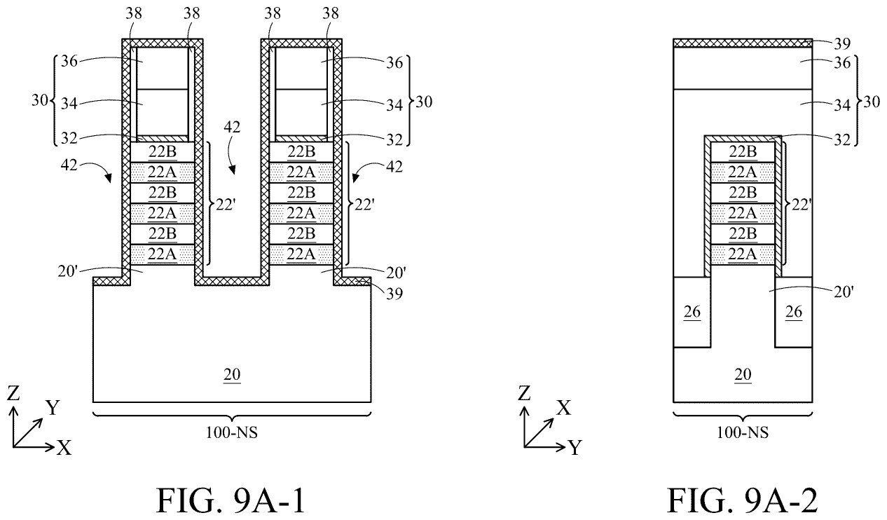

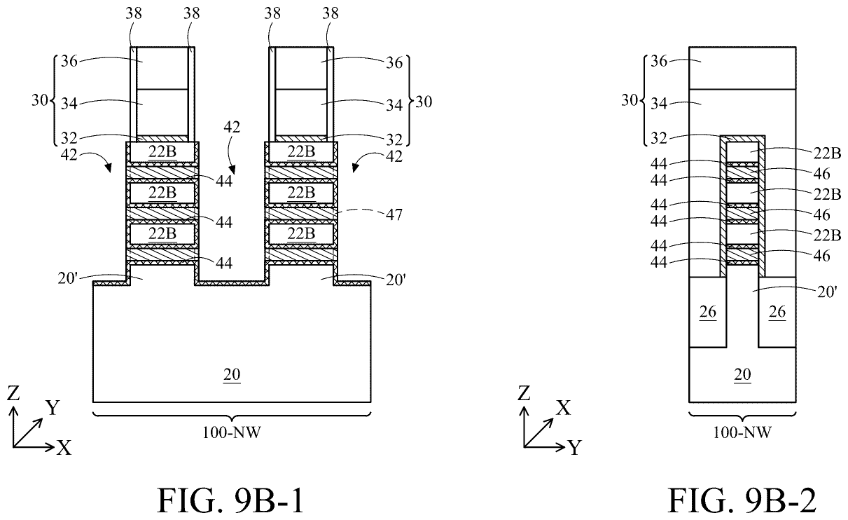

Depending on the control of the etching progress, some portions of dielectric layers 46 in the gaps between semiconductor layers 44 may be recessed to form recesses. Dashed lines 47 (FIG. 9B-1) schematically illustrate the positions of the outer surfaces of dielectric layer 46 when dielectric layers 46 are recessed. Dielectric layers 46 may be recessed less than, equal to, or more than the thickness of the sidewall portions of semiconductor layers 44.

FIGS. 10A-1 and 10A-2 illustrate the removal of the hard mask layer 39 in device region 100-NS, for example, through a wet etching process or a dry etching process. The respective process is illustrated as process 222 in the process flow 200 shown in FIG. 25. The sidewalls of sacrificial layers 22A and nanostructures 22B are thus exposed. The structure in device region 100-NW is shown in FIGS. 10B-1 and 10B-2.

Referring to FIGS. 11B-1 and 11B-2, a protection region 51 is formed. The formation process may include depositing protection region 51 into both of the device regions 100-NS and 100-NW, and removing the portion of protection region 51 in device region 100-NS, with the portion in device region 100-NW being left. The respective process is illustrated as process 224 in the process flow 200 shown in FIG. 25. In accordance with some embodiments, protection region 51 may be formed of silicon nitride or other materials that are different from the exposed materials of the structure shown in FIGS. 11A-1 and 11A-2. The top surface of protection region 51 may be higher than the topmost surface of nanostructures 22B by a height difference in the range between about 5 nm and about 10 nm. If the height difference is too big, the removal of protection region 51 in a subsequent process would be harder.

After the formation of the protection region 51 to protect device region 100-NW, inner spacers 50-NS are formed, as shown in FIGS. 11A-1 and 11A-2. The respective process is illustrated as process 226 in the process flow 200 shown in FIG. 25. In accordance with some embodiments, the sacrificial layers 22A in device region 100-NS are recessed to form lateral recesses, for example, through an isotropic etching process, which may be a dry etching process or a wet etching process.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

Inner spacers 50-NS are then formed. In accordance with some embodiments, the formation of inner spacers 50-NS includes depositing a conformal dielectric layer, which extends into the lateral recesses. Next, an etching process (also referred to as a spacer trimming process) is performed to trim the portions of the spacer layer outside of the lateral recesses, leaving the portions of the spacer layer in the lateral recesses. The remaining portions of the spacer layer are referred to as inner spacers 50-NS. Protection layer 51 is then removed. At the time inner spacers 50-NS are formed in device region 100-NS, no inner spacers are formed in device region 100-NW in accordance with some embodiments.

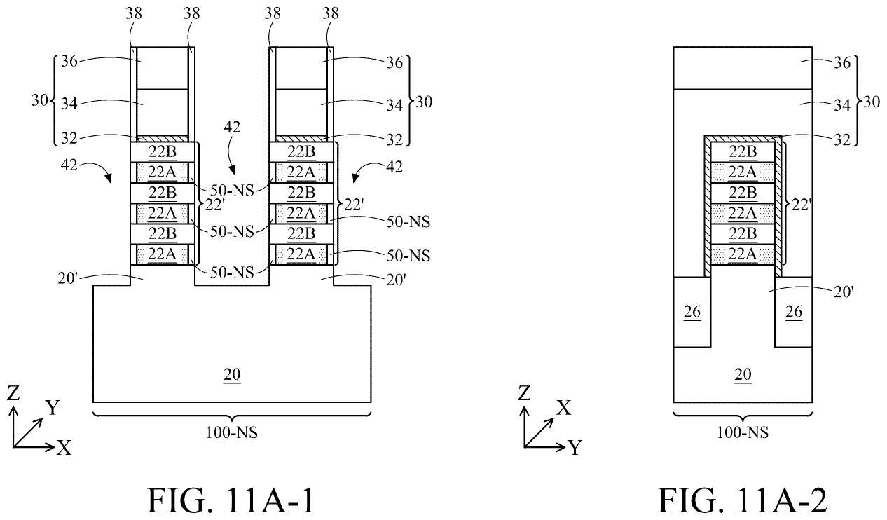

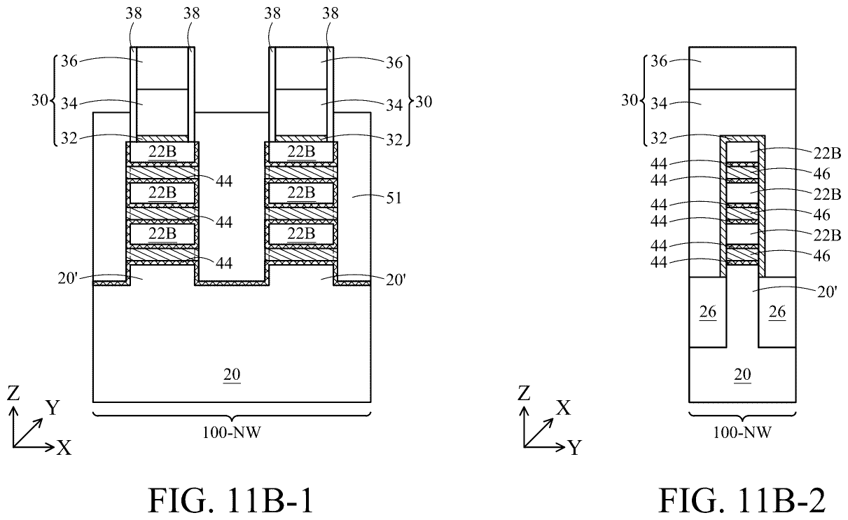

After the removal of protection layer 51, the structures are prepared for epitaxy by performing a cleaning process, which is configured to remove oxides on the future channel regions. The outer portions of semiconductor layers 44 (refer to FIG. 11B-1) on the sidewalls of nanostructures 22B may also be removed/recessed. The cleaning process may be performed, for example, using HF gas. During the cleaning process, dielectric layers 46 may also be recessed slightly, for example, by about 1 nm and about 2 nm. The resulting structure in device region 100-NW will be as shown in FIGS. 12B-1 and 12B-2.

When the cleaning process is performed, the structure in device region 100-NS is shown in FIGS. 12A-1 and 12A-2, which structure is essentially the same as the structure as shown in FIGS. 11A-1 and 11A-2.

FIGS. 13A-1 and 13A-2 illustrate the formation of source/drain regions 48-NS in device region 100-NS, and FIGS. 13B-1 and 13B-2 illustrate the formation of source/drain regions 48-NW in device region 100-NW. Source/drain region(s) may refer to a source or a drain, individually or collectively dependent upon the context. The respective process is illustrated as process 230 in the process flow 200 shown in FIG. 25.

The source/drain regions 48-NS and 48-NW, when being n-type regions, may comprise silicon or SiC and an n-type dopant such as As, P, Sb, or the like, or combinations thereof. For example, n-type source/drain regions 48-NS and 48-NW may comprise SiAs, SiP, SiCP, SiAsP, SiSb, or the like. The source/drain regions 48-NS and 48-NW, when being p-type regions, may comprise silicon, SiGe, or Ge, and further include a p-type dopant such as boron, indium, or combinations thereof. For example, the p-type semiconductor layer 48-NS and 48-NW may comprise SiGeB, GeB, or the like.

The formation of source/drain regions 48-NS and 48-NW may be performed through epitaxy processes. Furthermore, when source/drain regions 48-NS and 48-NW are of the same conductivity type, source/drain regions 48-NS and 48-NW may be epitaxially grown through the same epitaxy processes. In accordance with some embodiments, source/drain regions 48-NS and 48-NW may include a plurality of sub layers such as L0, L1, L2, and the like, with the different sub-layers having different compositions. For example, the concentration of the n-type or p-type dopant (depending on the conductivity type) of sub layer L0 may be lower than the concentration of the n-type or p-type dopant in sub layer L1.

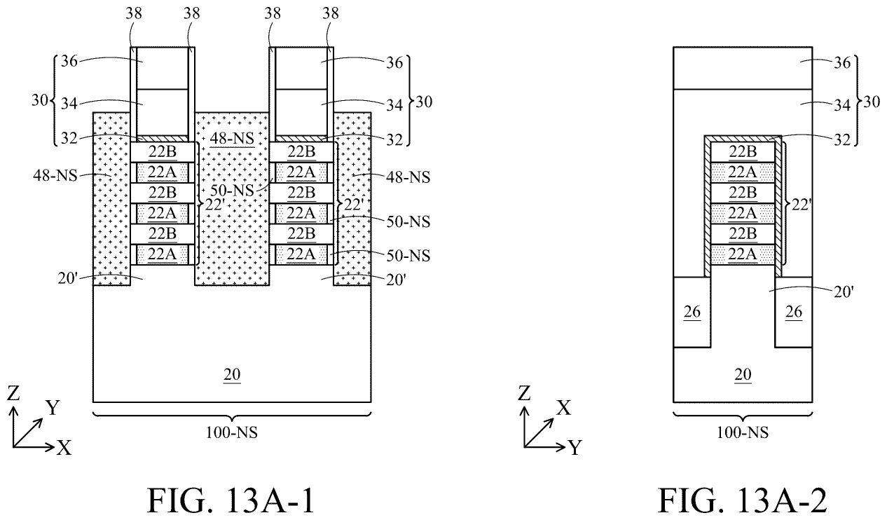

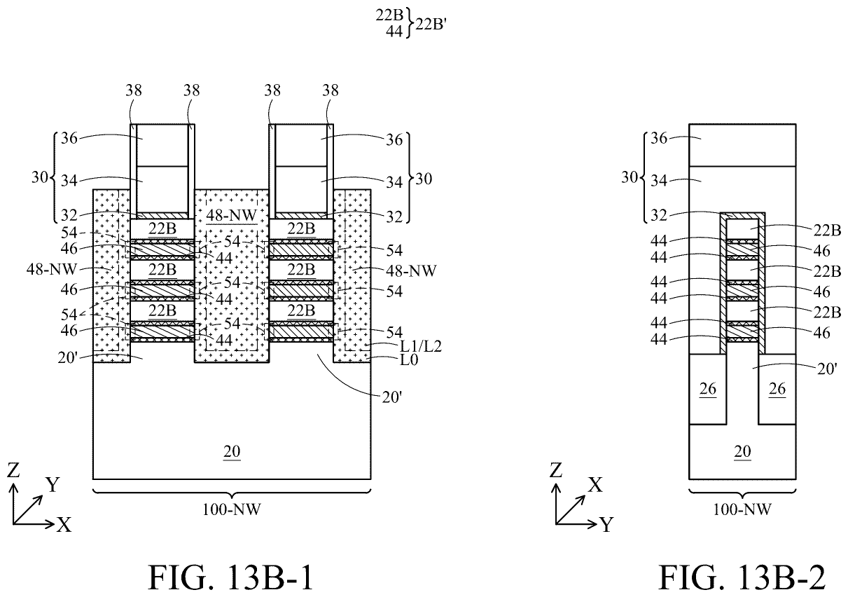

As shown in FIG. 13B-1 and 13B-2, source/drain regions 48-NW may contact dielectric layers 46 to form interfaces. In accordance with some embodiments, the interfaces may be recessed, and overlapped by overlying nanostructures 22B, and/or overlapping the underlying nanostructures 22B. Accordingly, source/drain regions 48-NW (such as sub layer Lo) may extend slightly between the overlying and underlying semiconductor layers 44. FIG. 13B-1 illustrate regions 54, into which source/drain regions 48-NW may extend. The extending distance may be equal to, slightly greater, or slightly smaller than the lateral dimension of inner spacers 50-NS (FIG. 13A-1). In accordance with alternative embodiments, the interfaces between source/drain regions 48-NW and dielectric layers 46 may be vertically aligned with the outer edges of nanostructures 22B.

In accordance with some embodiments, semiconductor layers 44 and nanostructures 22B collectively act as the channel regions of the resulting transistor in device region 100-NW, and are collectively referred to as nanostructures (or channel regions) 22B′. Due to the skin effect, there may be higher current density in semiconductor layers 44 and nanostructures 22B. Forming the semiconductor layers 44 comprising germanium may thus be advantageous in conducting higher currents.

FIGS. 14A-1, 14A-2, 14B-1 and 14B-2 illustrate the formation of Contact Etch Stop Layer (CESL) 66 and Inter-Layer Dielectric (ILD) 68. The respective process is illustrated as process 232 in the process flow 200 shown in FIG. 25. CESL 66 may be formed of silicon oxide, silicon nitride, silicon carbo-nitride, or the like, and may be formed using CVD, ALD, or the like. ILD 68 may include a dielectric material formed using, for example, FCVD, spin-on coating, CVD, or any other suitable deposition method. ILD 68 may be formed of an oxygen-containing dielectric material, which may be a silicon oxide, Phospho-Silicate Glass (PSG), Boro-Silicate Glass (BSG), Boron-Doped Phospho-Silicate Glass (BPSG), Undoped Silicate Glass (USG), or the like.

A planarization process such as a CMP process or a mechanical grinding process is performed to level the top surface of ILD 68. In accordance with some embodiments, the planarization process may remove hard masks 36 to reveal dummy gate electrodes 34, or may be stopped on, hard masks 36. In accordance with some embodiments, after the planarization process, the top surfaces of dummy gate electrodes 34 (or hard masks 36, FIGS. 13A-1, 13A-2, 13B-1, and 13B-2), gate spacers 38, and ILD 68 are level within process variations.

The dummy gate electrodes 34 (and hard masks 36, if remaining) and dummy gate dielectric 32 in device region 100-NS are then removed in one or more etching processes, so that recesses are formed. In device region 100-NS, each recess exposes and/or overlies portions of multilayer stacks 22′ (referring to FIG. 13A-1 and 13A-2), which include the future channel regions in subsequently completed nano-FETs. The respective process is illustrated as process 234 in the process flow 200 shown in FIG. 25. The portions of the multilayer stacks 22′, which act as the channel regions, are between neighboring pairs of the epitaxial source/drain regions 48-NS.

The recesses are then extended downwardly between nanostructures 22B by removing sacrificial layers 22A through etching. As may be realized from FIG. 13A-2, after the removal of dummy gate dielectric 32 and dummy gate electrode 34, the sidewalls of sacrificial layers 22A are exposed, and thus sacrificial layers 22A can be removed.

In device region 100-NW, the dummy gate stack 30 as shown in FIGS. 13B-1 and 13B-2 are also removed. The sidewalls of dielectric layers 46 and semiconductor layers 44 may be exposed. Semiconductor layers 44 may or may not be recessed slightly, and due to the material and the small thickness, are not removed.

Next, replacement gate stacks are formed, as shown in FIGS. 14A-1, 14A-2, 14B-1, and 14B-2. The respective process is illustrated as process 236 in the process flow 200 shown in FIG. 25. As shown in FIGS. 14A-1 and 14A-2, dielectrics 60, which include ILs and high-k dielectric layers (not shown separately) are formed and extending into the recesses formed due to the removal of the dummy gate stacks 30 and the sacrificial layers 22A. In accordance with some embodiments, the ILs are formed of silicon oxide, which may be formed through an oxidation process or a deposition process. The high-k dielectric layers are deposited conformally, for example, through a conformal deposition process such as ALD, CVD, or the like. The high-k dielectric layers may be formed of or comprise a high-k dielectric material, which may have a k value greater than about 7.0, and may include a metal oxide or a silicate of hafnium, aluminum, zirconium, lanthanum, manganese, barium, titanium, lead, and combinations thereof.

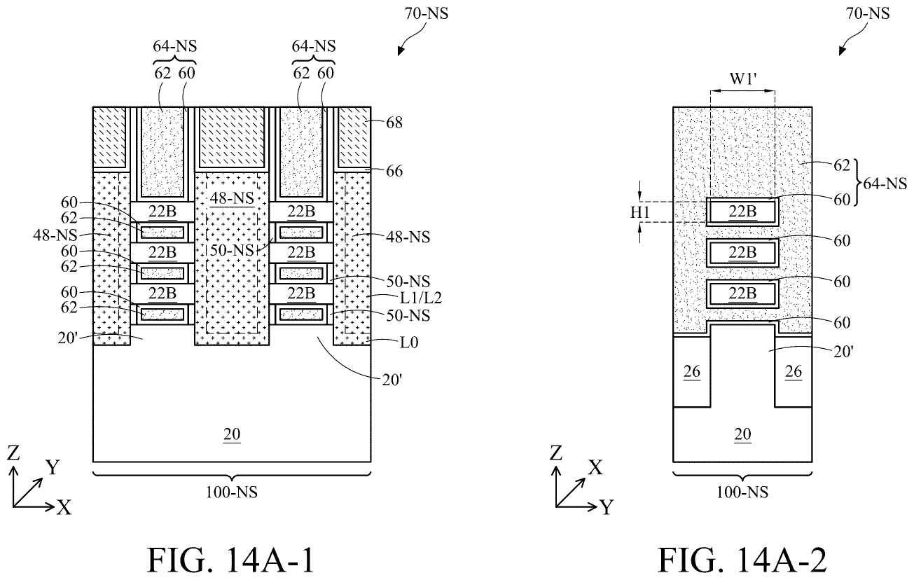

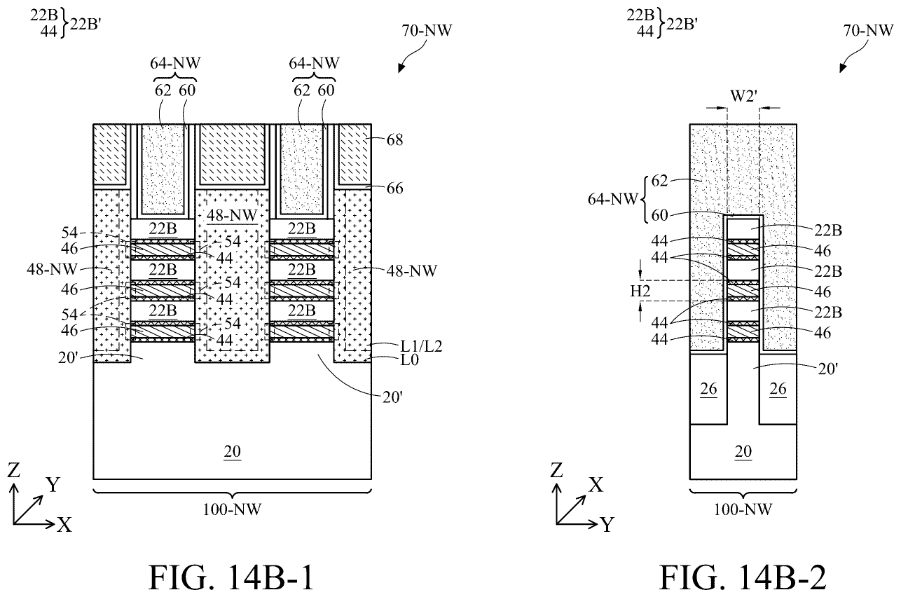

Gate electrodes 62 are deposited over the high-k dielectric layers. Gate electrodes 62 may include a metal-containing material such as TiN, TaN, TiAl, TiAlC, cobalt, ruthenium, aluminum, tungsten, combinations thereof, and/or multilayers thereof. The materials may be related to whether the resulting nanosheet transistor is a p-type transistor or an n-type transistor, and the work-function layers of the gate electrodes 62 are selected to have corresponding p-type or n-type work functions. Nanosheet transistor 70-NA is thus formed, which has sheet width W1′ (FIG. 14A-2). Width W1′ is close to width W1 (for example, with less than 20 percent variation) as shown in FIGS. 4 and 5A-2.

Referring to FIGS. 14B-1 and 14B-2, replacement gate stack 64-NW is also formed. Replacement gate stacks 64-NS and 64-NW may be formed sharing common formation processes, such as the removal of dummy gate stacks, and the deposition and the planarization of replacement gate dielectrics and replacement gate electrodes.

Different from the formation of replacement gate stack 64-NS in device region 100-NS, since the sacrificial layers 22A has already been removed in proceeding processes, and have been replaced by dielectric layers 46 and semiconductor layers 44, the recesses do not extend significantly between nanostructures 22B.

In accordance with some embodiments in which semiconductor layers 44 are formed of silicon or SiGe with a low germanium atomic percentage, semiconductor layers 44 (and nanostructures 22B) are not etched. When semiconductor layers 44 is formed of Ge or SiGe having a high germanium atomic percentage, semiconductor layers 44 may be laterally recessed slightly due to their small thicknesses.

As shown in FIGS. 14B-1 and 14B-2, replacement gate stack 64-NW do not include portions separating nanostructures 22B from each other. Rather, nanostructures 22B, dielectric layers 46, and semiconductor layers 44 collectively form a protruding fin, and the replacement gate stack 64-NW is formed on the sidewall and the top of the protruding fin. Nanowire transistor 70-NW is thus formed, which has sheet width W2′ (FIG. 14B-2), which is close to width W1 (for example, with less than 20 percent variation) as shown in FIGS. 4 and 5B-2. The channel regions of nanowire transistor 70-NW include nanostructures 22B′, which include nanostructures 22B and semiconductor layers 44.

FIGS. 15A-1, 15A-2, 15B-1, and 15B-2 through FIGS. 17A-1, 17A-2, 17B-1, and 17B-2 illustrate the formation of nanowire transistors 70-NS and 70-NW in accordance with alternative embodiments. The nanowire transistors 70-NS and 70-NW in accordance with these embodiments are essentially the same as that in FIGS. 14A-1, 14B-1, 14A-2, and 14B-2. The difference is that additional inner spacers 50-NW are formed in the nanowire transistor 70-NW in FIGS. 17B-1 and 17B-2, while no inner spacer is formed in the nanowire transistor 70-NW in FIGS. 14B-1 and 14B-2. Unless specified otherwise, the reference numerals in these embodiments represent like elements in the embodiments illustrated in FIGS. 1 through FIGS. 14A-1, 14A-2, 14B-1, and 14B-2.

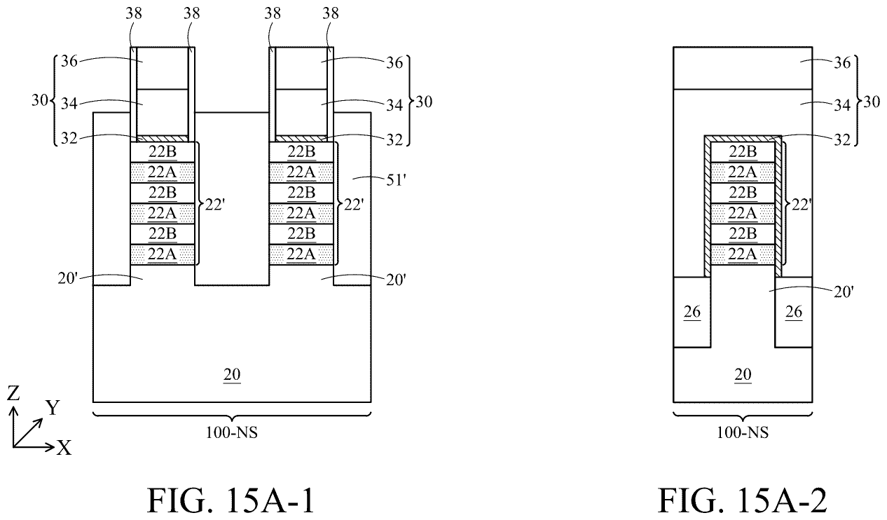

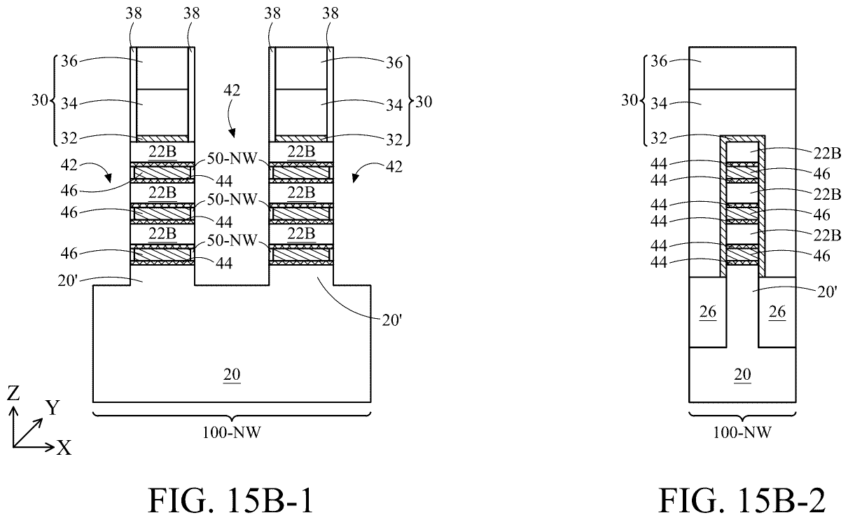

The initial steps of this embodiment are essentially the same as shown in FIGS. 1 through FIGS. 10A-1, 10A-2, 10B-1, and 10B-2. Next the process as shown in FIG. 15A-1, 15A-2, 15B-1, and 15B-2 are performed. A protection layer 51′ is formed in both of device regions 100-NS and 100-NW, and then removed from device region 100-NW, and left in device region 100-NS. Dielectric layers 46 (FIGS. 15B-1 and 15B-2) are then recessed, followed by filling a dielectric material into the recesses, forming inner spacers 50-NW, as shown in FIGS. 15B-1. Protection layer 51′ is then removed.

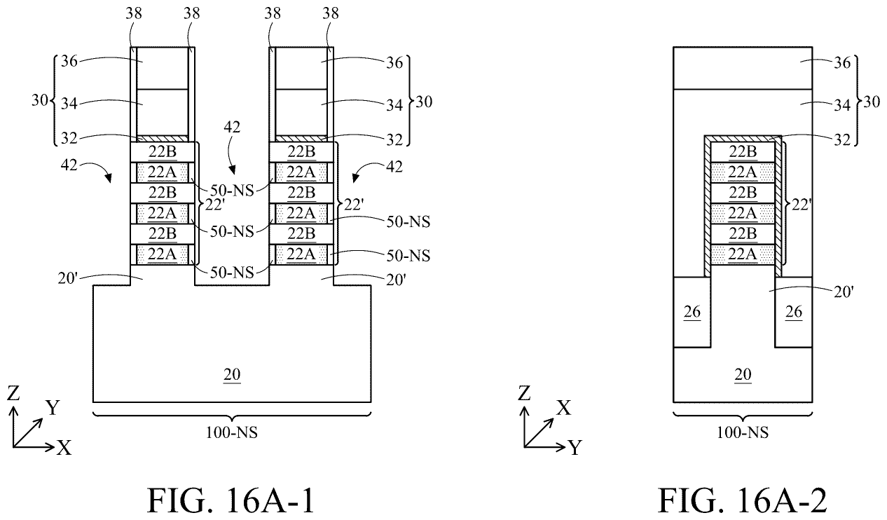

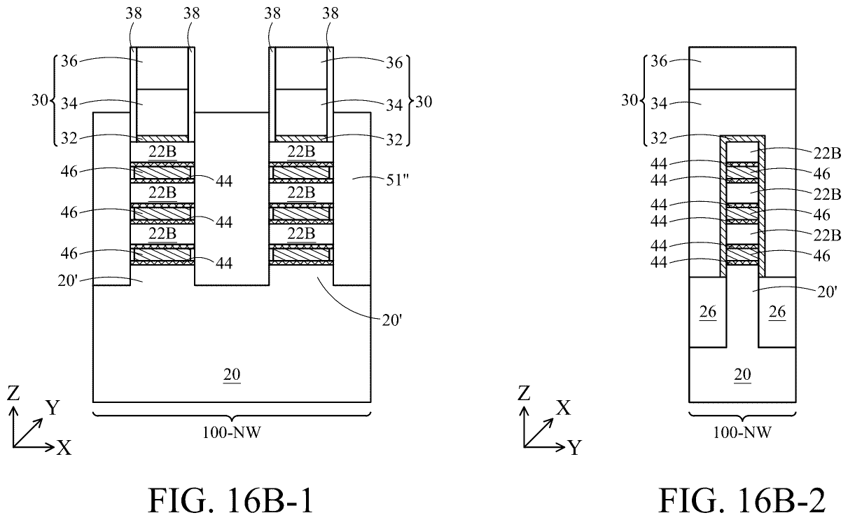

Next, the process as shown in FIG. 16A-1, 16A-2, 16B-1, and 16B-2 is performed to form inner spacers 50-NS in device region 100-NS. A protection layer 51″ is formed in both of device regions 100-NS and 100-NW, and then are removed from device region 100-NS and left in device region 100-NW. Sacrificial layers 22B are then recessed, followed by filling a dielectric material into the recesses, forming inner spacers 50-NS, as shown in FIGS. 16A-1. Protection layer 51″ is then removed. It is appreciated that the order of the processes of forming inner spacers 50-NW and 50-NS may be inversed.

Next, the processes as shown in FIGS. 12B-1 and 12B-2 (which may be or may not be performed) through FIGS. 14A-1, 14A-2, 14B-1 and 14B-2 are performed. FIGS. 17A-1, 17A-2, 17B-1 and 17B-2 illustrate the resulting structure, which are essentially the same as that shown in FIGS. 14A-1, 14A-2, 14B-1 and 14B-2, except inner spacers 50-NW are also formed.

In FIGS. 14A-2 and 17A-2, the sheet width W1′ may be greater than about 8 nm and smaller than about 80 nm, the spacing between the neighboring nanostructures 22B may be in the range between about 8 nm and about 10 nm. The thickness H1 of the nanostructures 22B may be in the range between about 4 nm and about 7 nm. Width W1′ is greater than thickness H1, with ratio W1′/H1 being in the range between about 1.6 and about 16. When ratio W1′/H1 is too high, it is difficult to form the structure and fill the gap between the nanosheets. When ratio W1′/H1 is too small, the current is not large enough.

In FIG. 14-B2 and 17B-2, the sheet width W2′ may be in the range between about 4 nm and about 6 nm, the spacing between the neighboring nanostructures 22B may be in the range between about 3 nm and about 5 nm. The thickness H2 of the nanostructures 22B′ may be in the range between about 9 nm and about 11 nm. Width W2′ is closer to, and may be smaller than thickness H2, with ratio W2′/H2 being in the range between about 0.3 and about 0.7. When ratio W2′/H2 is too high, replacement gate stack may extend between nanostructures 22B. When ratio W2′/H2 is too small, the current is not large enough.

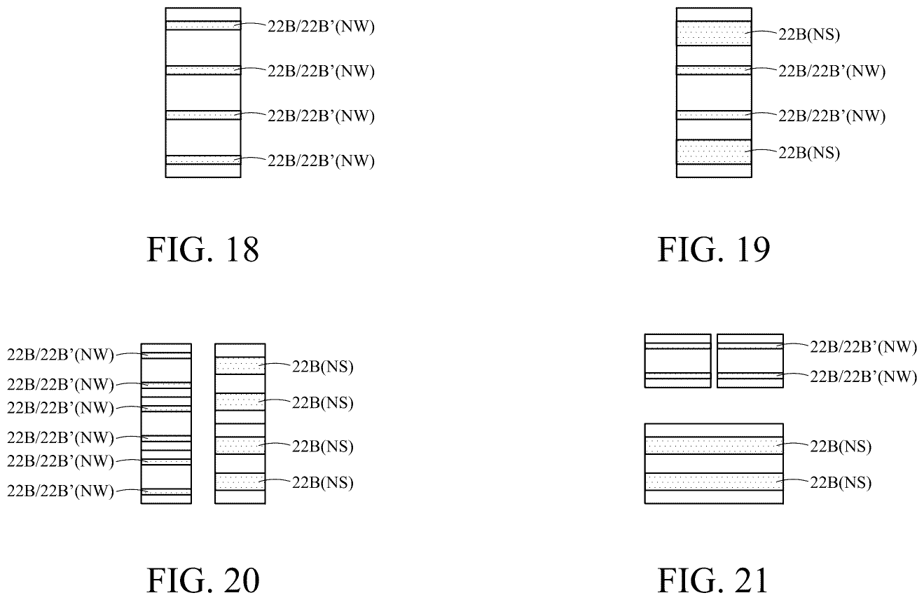

FIGS. 18-22 illustrate the top views of some nanosheets and nanowires, which are adopted to form the nanosheet transistors and nanowire transistors as discussed. FIGS. 18 and 19 illustrate the top views of nanowires (22B or 22B′) and nanosheets 22B, respectively. Adopting hybrid nanosheet transistors and nanowire transistors may reduce the usage of chip area without sacrificing circuit performance. For example, FIG. 20 illustrates that the nanowires 22B/22B′ for forming three nanowire transistors (assuming two nanowires 22B/22B′ form one nanowire transistor) may occupy the chip area of two nanosheet transistors (assuming two nanosheets 22B form one nanosheet transistor). When drive current is not demanding, nanowire transistors may be adopted to reduce chip area usage. FIG. 21 illustrates that nanosheet transistors and nanowire transistors may be aligned to the same columns.

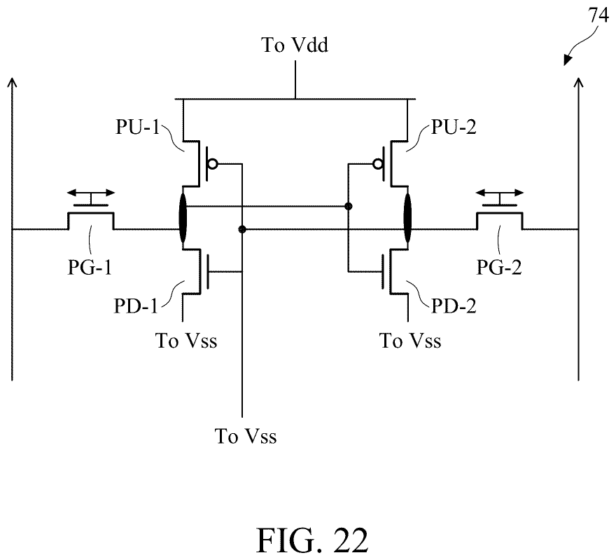

Nanosheet transistors have higher (drive) currents but occupy more chip area. Nanowire transistor have lower chip area usage but have lower (drive) currents. The hybrid nanosheet transistors and nanowire transistors may be adopted to suit to customized requirements. For example, FIG. 22 illustrates a static random-access memory (SRAM) cell 74, which includes pull-up transistors PU-1 and PU-2, pull-down transistors PD-1 and PD-2, and pass-gate transistor PG-1 and PG-2. In accordance with some embodiments, when the circuits are desired to be high-density circuits, all of the transistors in SRAM cell 74 are formed as nanowire transistors 70-NW since the current requirement is not demanding. In which case, the transistor density in the SRAM may be improved by more than 15 percent compared to the circuits that are formed of nanosheet transistors.

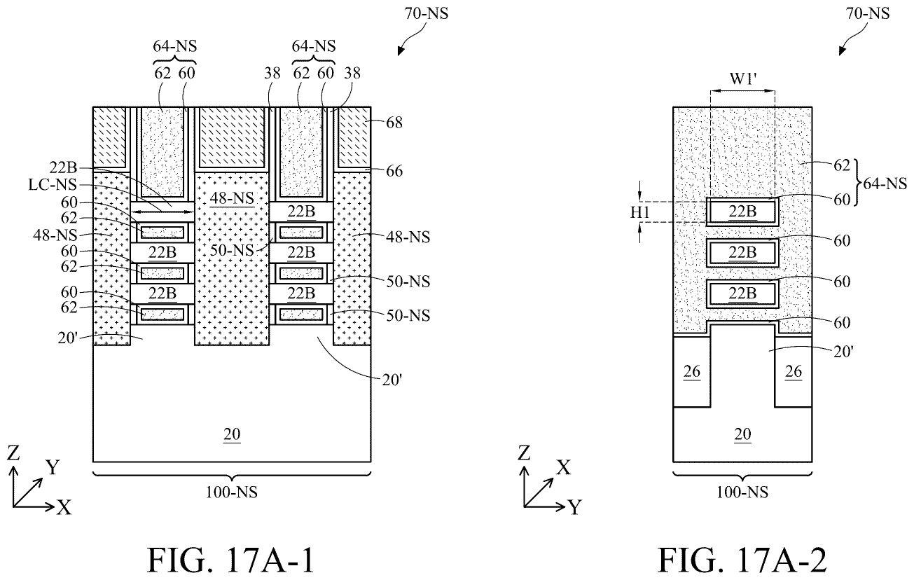

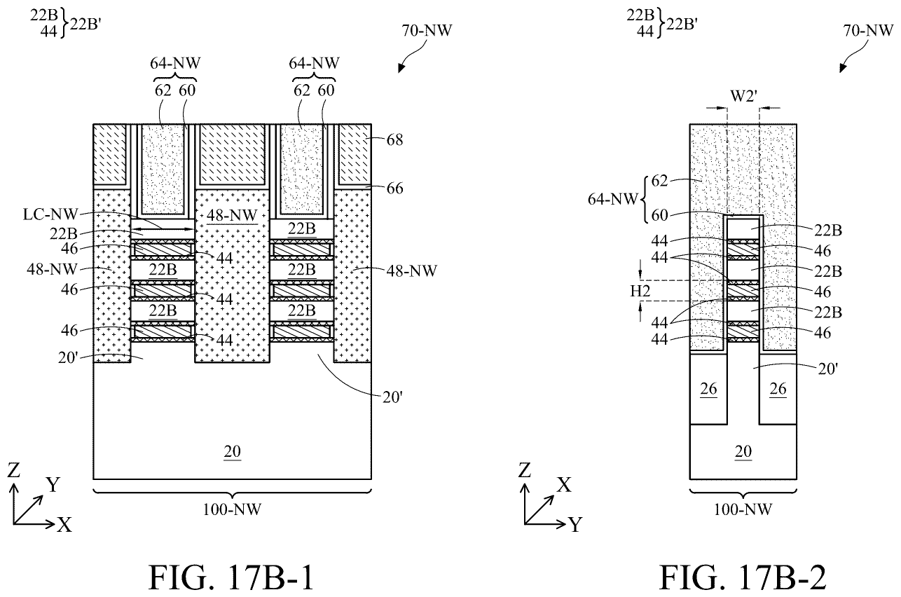

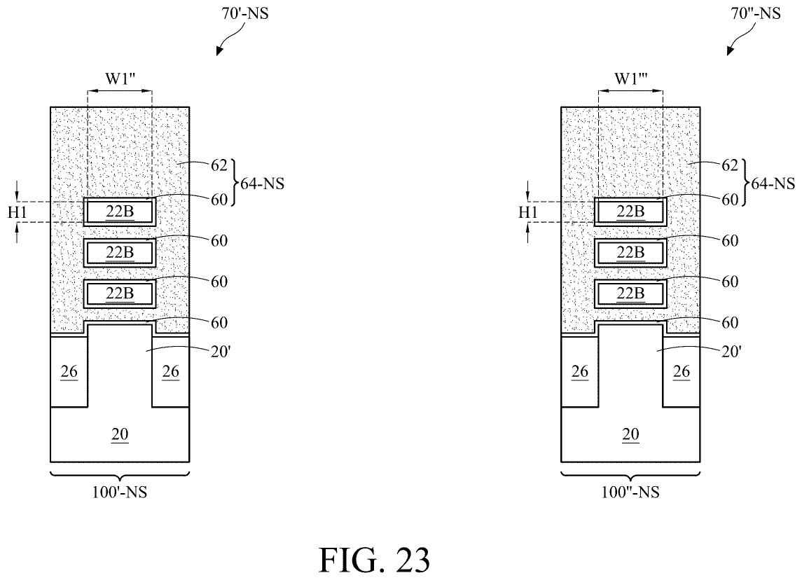

The nanosheet transistors in a same device die (and in a same wafer) may have different channel widths so that they may have different drive currents to suit to customized circuit requirement. For example, FIG. 23 illustrates a nanosheet transistor 70′-NS in device region 100′-NS having channel width W1″, and nanosheet transistor 70″-NS in device region 100″-NS having channel width W1″. In accordance with some embodiments, channel width W1″ is smaller than channel width W1′ (FIG. 17A-2), and channel width W1″' is greater than channel width W1′.

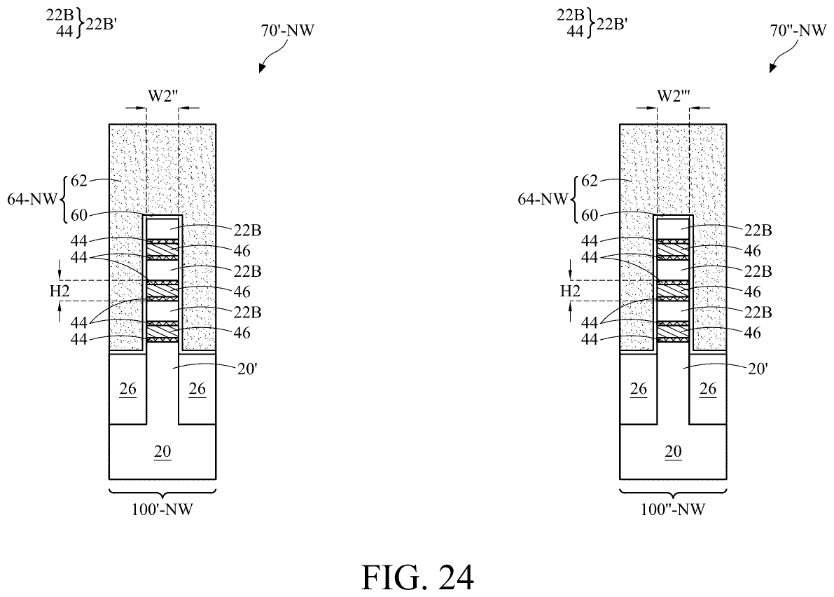

FIG. 24 illustrates a nanowire transistor 70′-NW in device region 100′-NW having channel width W2″, and nanowire transistor 70″-NW in device region 100″-NW having channel width W2′'. In accordance with some embodiments, channel width W2″ is smaller than channel width W2′ (FIG. 17B-2), and channel width W2″ is greater than channel width W2′. The transistors with greater channel widths may have higher drive currents.

In accordance with alternative embodiments, when the circuits are desired to be high-current circuits, pull-down transistors PD-1 and PD-2 are formed as nanosheet transistors to meet the high current requirements of the pull-down transistors. Pull-up transistors PU-1 and PU-2 and pass-gate transistor PG-1 and PG-2, on the other hand, do not require high currents, and hence are formed as nanowire transistors. In which case, the transistor density in the SRAM may be improved by more than 5 percent compared to the circuits that are formed of nanosheet transistors, while may still meet or exceed the circuit performance requirement.

In addition, the gate stacks of nanowire transistors do not extend between the channels, and the parasitic capacitance between source/drain regions and gate stacks is reduce, and AC gain is improved. The nanowires are also thickened due to the epitaxy, and strain is improved.

The embodiments of the present disclosure have some advantageous features. By forming the hybrid devices including both of the nanosheet transistors and nanowire transistors, chip area usage may be reduced and device density may be increased, without sacrificing circuit performance. The nanosheet transistors and nanowire transistors may share common formation processes, thus reducing manufacturing cost.

In accordance with some embodiments of the present disclosure, a method comprises patterning stacked layers to form a first multi-layer stack and a second multi-layer stack, each comprising a plurality of sacrificial layers and a plurality of nanostructures located alternatingly, wherein the second multi-layer stack is wider than the first multi-layer stack; forming a nanosheet transistor based on the first multi-layer stack, wherein the nanosheet transistor comprises first channel regions having a first width; and a first gate stack on the first channel regions; and forming a nanowire transistor based on the second multi-layer stack, wherein the nanowire transistor comprises second channel regions narrower than the first channel regions; and a second gate stack on the second channel regions.

In an embodiment, the forming the nanowire transistor comprises removing the plurality of sacrificial layers in the second multi-layer stack to leave gaps; and epitaxially growing semiconductor layers in the gaps. In an embodiment, the forming the nanowire transistor further comprises, after the semiconductor layers are grown in the gaps, filling the gaps with dielectric layers, wherein a dielectric layer of the dielectric layers physically contacts an overlying one and an underlying one of the semiconductor layers. In an embodiment, the epitaxially growing the semiconductor layers comprises growing silicon layers.

In an embodiment, the epitaxially growing the semiconductor layers comprises growing germanium-containing layers. In an embodiment, the forming the nanosheet transistor comprises removing the plurality of sacrificial layers in the first multi-layer stack; and forming the first gate stack comprising portions between the plurality of nanostructures in the first multi-layer stack. In an embodiment, the first channel regions of the nanosheet transistor have a smaller height than the second channel regions of the nanowire transistor. In an embodiment, the method further comprises forming first inner spacers for the nanosheet transistor, wherein the first gate stack comprising portions in regions between the first inner spacers, and the nanowire transistor is free from inner spacers.

In an embodiment, the method further comprises forming first inner spacers for the nanosheet transistor, wherein the first gate stack comprising portions in regions between the first inner spacers; and forming second inner spacers for the nanowire transistor, wherein dielectric layers are located between the second inner spacers. In an embodiment, the method comprises forming a static random-access memory cell, wherein the nanosheet transistor is formed as a pull-down transistor of the static random-access memory cell, and wherein the nanowire transistor is formed as a pull-up transistor of the static random-access memory cell.

In accordance with some embodiments of the present disclosure, a structure comprises a bulk semiconductor substrate; a nanosheet transistor over the bulk semiconductor substrate, wherein the nanosheet transistor comprises first channel regions, wherein upper ones of the first channel regions overlap lower ones of the first channel regions; and a first gate stack on the first channel regions; and a nanowire transistor over the bulk semiconductor substrate, wherein the nanowire transistor comprises second channel regions narrower than the first channel regions, wherein upper ones of the second channel regions overlap lower ones of the second channel regions; and a second gate stack on the second channel regions.

In an embodiment, the first channel regions have a first thickness, and the second channel regions have a second thickness greater than the first thickness. In an embodiment, the first channel regions comprise a first semiconductor material; and one of the second channel regions comprises a first layer comprising the first semiconductor material; and a second layer comprising a second semiconductor material different from the first semiconductor material. In an embodiment, the first channel regions and the second channel regions comprise a same semiconductor material.

In an embodiment, the first gate stack comprises intermediate portions between neighboring ones of the first channel regions; and the second gate stack comprises dielectric layers between neighboring ones of the second channel regions. In an embodiment, the nanosheet transistor comprises first inner spacers contacting first opposite sidewall of the intermediate portions of the first gate stack; and the nanowire transistor comprises second inner spacers contacting second opposite sidewall of the dielectric layers. In an embodiment, the structure comprises a static random-access memory cell comprising the nanosheet transistor as a pull-down transistor; and the nanowire transistor as a pull-up transistor.

In accordance with some embodiments of the present disclosure, a structure comprises a nanowire transistor comprising a protruding structure comprising a plurality of channel regions; and a plurality of dielectric regions between the plurality of channel regions; a first source/drain region and a second source/drain region on opposite sides of, and joining to, the plurality of channel regions and the plurality of dielectric regions; and a gate stack on the protruding structure. In an embodiment, the plurality of dielectric regions comprise a plurality of dielectric layers; and a plurality of inner spacers on opposite sides of and contacting the plurality of dielectric layers.

In an embodiment, the plurality of channel regions comprise a first plurality of semiconductor layers comprising a first semiconductor material; and a second plurality of semiconductor layers comprising a second dielectric material different from the first semiconductor material, wherein the second plurality of semiconductor layers are on the first plurality of semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
patterning stacked layers to form a first multi-layer stack and a second multi-layer stack, each comprising a plurality of sacrificial layers and a plurality of nanostructures located alternatingly, wherein the second multi-layer stack is wider than the first multi-layer stack;
forming a nanosheet transistor based on the first multi-layer stack, wherein the nanosheet transistor comprises:
first channel regions having a first width; and
a first gate stack on the first channel regions; and
forming a nanowire transistor based on the second multi-layer stack, wherein the nanowire transistor comprises:
second channel regions narrower than the first channel regions; and
a second gate stack on the second channel regions;
wherein forming the nanowire transistor comprises:
removing the plurality of sacrificial layers in the second multi-layer stack to leave gaps; and
epitaxially growing semiconductor layers in the gaps; and
wherein forming the nanosheet transistor comprises:
removing the plurality of sacrificial layers in the first multi-layer stack; and
forming the first gate stack comprising portions between the plurality of nanostructures in the first multi-layer stack.
